(19) United States
(12) Patent Application Publication
(10) Pub. No.: US 2014/0176116 A1
(43) Pub. Date: Jun. 26, 2014

(54) QUANTIFYING SILICON DEGRADATION IN AN INTEGRATED CIRCUIT

(71) Applicant: NVIDIA CORPORATION, Santa Clara, CA (US)

(72) Inventors: Hemant KUMAR, Fremont, CA (US); Matthew Raymond LONGNECKER, San Jose, CA (US); Brian SMITH, Mountain View, CA (US)

(73) Assignee: NVIDIA CORPORATION, Santa Clara, CA (US)

(21) Appl. No.: 13/723,139

(22) Filed: Dec. 20, 2012

(51) Int. Cl. G01R 23/02; H01L 25/00

(52) U.S. Cl. CPC G01R 23/02; H01L 25/00
USPC 324/76.41; 327/564

(57) ABSTRACT

A first instance and a second instance of an oscillating circuit are each formed as part of an integrated circuit and are used to monitor degradation over time of one or more portions of the integrated circuit. The first instance of the oscillating circuit is configured to be coupled to a power source during normal operation of the integrated circuit and the second instance is configured to be decoupled from the power source. Over the lifetime of the integrated circuit, the first instance undergoes degradation from use while the second instance of the oscillating circuit remains unpowered, therefore experiencing essentially no use-related degradation. During a testing operation, the second instance can be used as a reference circuit that accurately quantifies use-related degradation of the first instance of the oscillating circuit and, by extension, one or more portions of the integrated circuit.

### BACKGROUND OF THE INVENTION

1. Field of the Invention

Embodiments of the present invention relate generally to integrated circuits and, more specifically, to quantifying silicon degradation in an integrated circuit.

2. Description of the Related Art

In integrated circuits (ICs) and related subsystems, microprocessors and other components can typically be operated across a range of voltages and frequencies. Consequently, a microprocessor or other component of an IC that is operated at a higher frequency (and correspondingly higher voltage) in this range has faster computing performance and higher energy consumption than when operated at a lower frequency (and correspondingly lower voltage). A feature key for saving power and reducing heat generation in ICs is the implementation of dynamic voltage and frequency scaling (DVFS), a combination of dynamic voltage scaling and dynamic frequency scaling. Dynamic voltage scaling is a power management technique in which the voltage used in a component is increased or decreased dynamically, depending upon the usage of the component, and dynamic frequency scaling involves adjusting the frequency of a component dynamically, depending on the usage of the component.

Over the lifetime of an IC, various mechanisms result in the degradation of sub-circuits and other components of the IC, including hot-carrier injection (HCI), negative bias temperature instability (NBTI), and positive bias temperature instability (PBTI) or “charge trapping.” The degradation caused by HCI, NBTI, and PBTI generally reduces the intrinsic speed of an affected sub-circuit and component, thereby altering the voltage-frequency curve that describes the minimum voltage required to operate the IC component at a given frequency. As an IC component degrades from use, a higher minimum voltage is required for running at a particular frequency. Consequently, a “voltage margin” is commonly incorporated into the voltage-frequency curves of an IC device to anticipate such degradation and prevent functional failures in the IC device later in the functional life of the device. Unfortunately, the inclusion of voltage margin in the voltage-frequency curve of an IC device results in wasted power consumption and unnecessarily slow performance for much of the lifetime of the IC device.

Accordingly, there is a need in the art for a technique to reduce voltage margins used in IC devices without increasing the likelihood of functional failures in such devices.

### SUMMARY OF THE INVENTION

One embodiment of the present invention sets forth a subsystem of an integrated circuit configured to monitor the degradation over time of one or more portions of the integrated circuit. The subsystem includes a first instance and a second instance of an oscillating circuit that are each formed as part of an integrated circuit. The first instance of the oscillating circuit is configured to be coupled to a power source during operation of the semiconductor system. The second instance of the oscillating circuit is configured to be decoupled from the power source during operation of the integrated circuit and coupled to the power source during a testing operation.

One advantage of the afore-described embodiment is that accurate measurement of semiconductor degradation over time in an integrated circuit can be made periodically throughout the lifetime of the integrated circuit. This allows for significantly reduced voltage margins, thereby improving computing performance and reducing power consumption of the integrated circuit.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram illustrating a computer system configured to implement one or more aspects of the present invention.

FIG. 2 is a schematic illustration of a degradation measurement circuit, arranged according to one embodiment of the invention.

FIG. 3 is a schematic illustration of a degradation measurement circuit, according to one embodiment of the invention.

FIG. 4 is a graph illustrating voltage-frequency curves of an IC configured with a degradation measurement circuit, according to one embodiment of the invention.

FIG. 5 is a schematic illustration of a multi-core processor, according to one embodiment of the invention.

FIG. 6 is a flowchart of method steps for determining the degradation of a circuit in a semiconductor system, according to one embodiment of the present invention.

FIG. 7 illustrates a computing device in which one or more embodiments of the present invention may be implemented.

For clarity, identical reference numbers have been used, where applicable, to designate identical elements that are common between figures. It is contemplated that features of one embodiment may be incorporated in other embodiments without further recitation.

### DETAILED DESCRIPTION

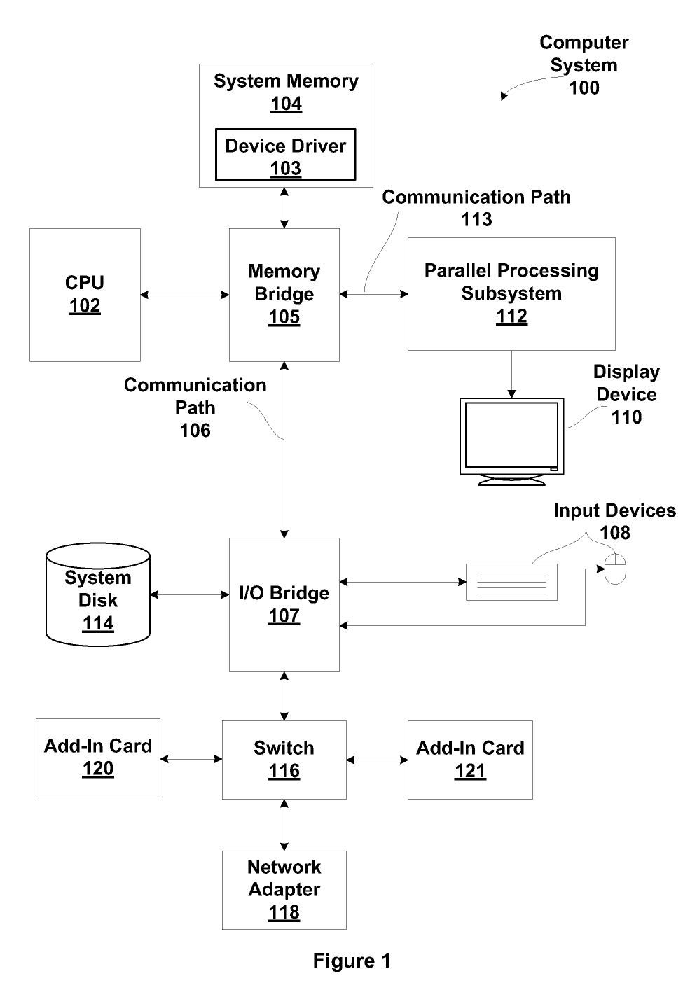

FIG. 1 is a block diagram illustrating a computer system 100 configured to implement one or more embodiments of the present invention. Computer system 100 includes a central processing unit (CPU) 102 and a system memory 104 communicating via an interconnection path that may include a memory bridge 105. Memory bridge 105, which may be, e.g., a Northbridge chip, is connected via a bus or other communication path 106 (e.g., a HyperTransport link) to an I/O (input/output) bridge 107. I/O bridge 107, which may be, e.g., a Southbridge chip, receives user input from one or more user input devices 108 (e.g., keyboard, mouse) and forwards the input to CPU 102 via communication path 106 and memory bridge 105. A parallel processing subsystem 112 is coupled to memory bridge 105 via a bus or second communication path 113 (e.g., a Peripheral Component Interconnect (PCI) Express, Accelerated Graphics Port, or HyperTransport link). In one embodiment parallel processing subsystem 112 is a graphics subsystem that delivers pixels to a display device 110 that may be any conventional cathode ray tube, liquid crystal display, light-emitting diode display, or the like. A system disk 114 is also connected to I/O bridge 107 and may be configured to store content and applications and data for use by CPU 102 and parallel processing subsystem 112. System disk 114 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices.

A switch 116 provides connections between I/O bridge 107 and other components such as a network adapter 118 and various add-in cards 120 and 121. Other components (not explicitly shown), including universal serial bus (USB) or other port connections, compact disc (CD) drives, digital versatile disc (DVD) drives, film recording devices, and the like, may also be connected to I/O bridge 107. The various communication paths shown in FIG. 1, including the specifically named communication paths 106 and 113 may be implemented using any suitable protocols, such as PCI Express, AGP (Accelerated Graphics Port), HyperTransport, or any other bus or point-to-point communication protocol(s), and connections between different devices may use different protocols as is known in the art.

In one embodiment, the parallel processing subsystem 112 incorporates circuitry optimized for graphics and video processing, including, for example, video output circuitry, and constitutes a graphics processing unit (GPU). In another embodiment, the parallel processing subsystem 112 incorporates circuitry optimized for general purpose processing, while preserving the underlying computational architecture, described in greater detail herein. In yet another embodiment, the parallel processing subsystem 112 may be integrated with one or more other system elements in a single subsystem, such as joining the memory bridge 105, CPU 102, and I/O bridge 107 to form a system on chip (SoC). In some embodiments, parallel processing system 112 may include multiple processors, such as parallel processor units.

It will be appreciated that the system shown herein is illustrative and that variations and modifications are possible. The connection topology, including the number and arrangement of bridges, the number of CPUs 102, and the number of parallel processing subsystems 112, may be modified as desired. For instance, in some embodiments, system memory 104 is connected to CPU 102 directly rather than through a bridge, and other devices communicate with system memory 104 via memory bridge 105 and CPU 102. In other alternative topologies, parallel processing subsystem 112 is connected to I/O bridge 107 or directly to CPU 102, rather than to memory bridge 105. In still other embodiments, I/O bridge 107 and memory bridge 105 might be integrated into a single chip instead of existing as one or more discrete devices. Large embodiments may include two or more CPUs 102 and two or more parallel processing subsystems 112. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

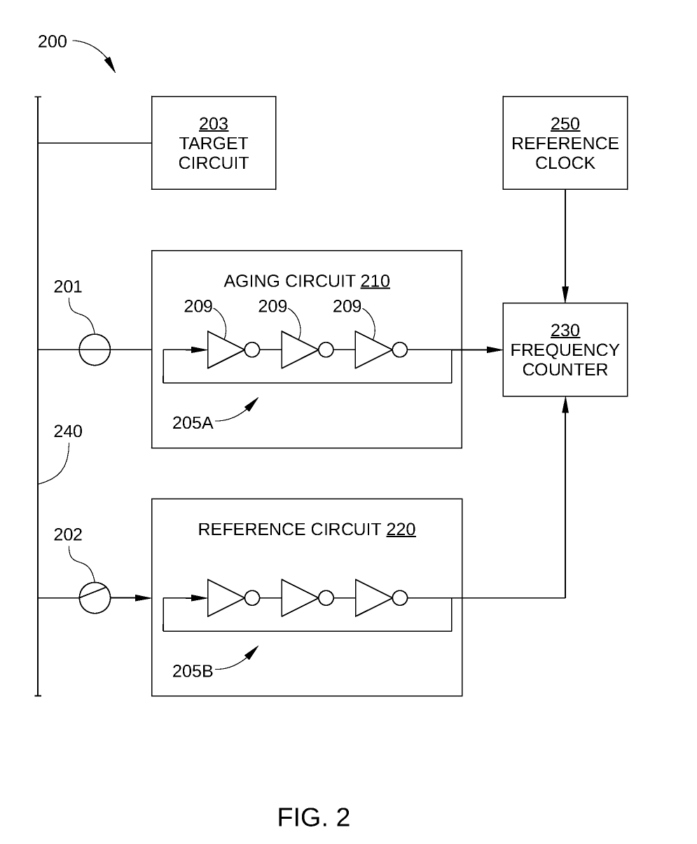

FIG. 2 is a schematic illustration of a degradation measurement circuit 200, arranged according to one embodiment of the invention. Degradation measurement circuit 200 includes an aging circuit 210, a reference circuit 220, and a frequency counter 230, and is configured to enable accurate measurement of the degradation of one or more portions of an IC. For example, degradation measurement circuit 200 may be configured to measure degradation over time of a target sub-circuit 203. Target sub-circuit 203 may include one or more specific components or subsystems of the IC configured with degradation measurement circuit 200, such as standard voltage threshold transistors (SVTs), low voltage-threshold (LVT) transistors, static random-access memory (SRAM), and interconnects subject to wire delay, among others. In some embodiments, target sub-circuit 203 represents a critical path of an IC such as CPU 102 or a processor in parallel processing subsystem 112. Suitable ICs that may include degradation measurement circuit 200 and therefore can be monitored thereby may be stand-alone ICs, composite ICs such as SoCs, and subsystems of an SoC. For example, degradation measurement circuit 200 may be configured as part of CPU 102 in FIG. 1, parallel processing units of parallel processing subsystem 112 in FIG. 1, or any other IC where implementing such a circuit is technically feasible.

Aging circuit 210 includes an oscillating circuit 205A, such as a ring oscillator, and is coupled to a power source 240 during operation of CPU 102, parallel processing subsystem 112, or other IC. As shown in FIG. 2, aging circuit 210 is coupled to the same power source as target sub-circuit 203. In addition, aging circuit 210 is shown as being coupled to power source 240 via a normally closed switching device 201. However, in other embodiments, aging circuit 210 may be coupled to power source 240 using any technically feasible structure without exceeding the scope of the invention. Power source 240 is a power source for one or more portions of CPU 102, parallel processing subsystem 112, or other IC, such as a voltage rail. In some embodiments, power source 240 is the main voltage rail of an IC.

Because aging circuit 210 is powered during operation of CPU 102, parallel processing subsystem 112, or other IC of interest, aging circuit 210 undergoes degradation associated with use that is proportional to that experienced by target sub-circuit 203. For example, in one embodiment, target circuit 203 includes one or more LTV transistors, and oscillating circuit 205A is configured for measuring the transistor-level performance of target circuit 203. In such an embodiment, oscillating circuit 205A may include an odd number of inverters 209 and therefore continue to oscillate when coupled to power source 240. In this embodiment, because oscillating circuit 205A is ringing throughout the life of the IC that includes target circuit 203, and is operated at the same voltage as target circuit 203, transistors in oscillating circuit 205A age in a similar fashion to the transistors in target circuit 203. Thus, target circuit 203 and oscillating circuit 205A both slow down over time in a corresponding way when measured at a given voltage and temperature. In such embodiments, oscillating circuit 205A may be configured to oscillate at substantially the same frequency as target circuit 203. Alternatively, oscillating circuit 205A may be configured to oscillate at a different frequency than target circuit 203, and measurements of oscillating circuit 205A are scaled accordingly when determining degradation that has occurred in target circuit 203.

Reference circuit 220 includes an oscillating circuit 205B, and is also coupled to the same power source as aging circuit 210, i.e., power source 240. Oscillating circuit 205B is a second instance of oscillating circuit 205A. Consequently, except for manufacturing variation, oscillating circuit 205B is configured to be substantially identical to oscillating circuit 205A. Unlike aging circuit 210, reference circuit 220 is not coupled to a power source during operation of the IC that includes target circuit 203, and is generally only powered during testing this IC. In the embodiment illustrated in FIG. 2, reference circuit 220 is coupled to power source 240 via a normally open switching device 202, but any technically feasible structure or device may be used to couple reference circuit 220 to power source 240 using without exceeding the scope of the invention.

Because reference circuit 220 is generally not powered during operation of the IC that includes target circuit 203, and testing of this IC typically occurs periodically and over short intervals, reference circuit 220 undergoes essentially no degradation associated with use. Thus, reference circuit 220 can be used as an absolute reference for measuring degradation of aging circuit 210 and, by extension, target circuit 203.

It is noted that various configurations of ring oscillators and other oscillating circuits are known and can be readily devised whose oscillation speed is proportional to different characteristics of sub-circuits in an IC. In this way, a desired behavior of the many transistors and other components that undergo degradation with use over the lifetime of an IC can be quantified. For example, oscillating circuits 205A and 205B can be configured with an oscillation speed that is proportional to wire speed, transistor speed, transistor leak rate, etc. In addition, oscillating circuits 205A and 205B can be configured to quantify the behavior SRAM, NAND gates, NOR gates, and the like. Thus, the embodiment of oscillating circuits 205A and 205B illustrated in FIG. 2 is for illustrative purposes only and is not intended to limit the scope of the invention. Any technically feasible oscillating circuit may be used in degradation measurement circuit 200, and may have a different number of inverters, inputs, and/or other components than those depicted in FIG. 2. Furthermore, in some embodiments, degradation measurement circuit 200 may include multiple frequency counters 230. For example, in some embodiments, degradation measurement circuit 200 includes parallel frequency counters 230, with frequency counter 230 per instance to allow counting at the same time in parallel.

In operation, degradation measurement circuit 200 can be used to periodically quantify changes in performance of target circuit 203. As noted above, during normal operation of an IC that includes degradation measurement circuit 200, aging circuit 210 is coupled to power source 240. Periodically, a test of aging circuit 210 is performed by coupling reference circuit 220 to power source 240 and measuring the resulting frequency of aging circuit 210 and reference circuit 220 with frequency counter 230. In the embodiment illustrated in FIG. 2, frequency counter 230 also receives input from a reference clock 250. Because aging circuit 210 and reference circuit 220 are fabricated to be as close to identical as practicable given unavoidable variations in manufacturing processes. Furthermore, aging circuit 210 and reference circuit 220 are coupled to the same power source during the testing process, so that instantaneous variations in supply voltage to aging circuit 210 and reference circuit 220 do not significantly affect test results.

The use of aging circuit 210 and reference circuit 220 as described above provides a more accurate reference of the absolute change in performance of a sub-circuit other techniques, such as measuring sub-circuit performance and comparing the measurement to performance of the sub-circuit prior to aging. This is because the initial measurement is taken under conditions that will generally change over time. For instance, voltage can vary due to degradation of a voltage regulator, and/or because a different voltage regulator may be used at different times (e.g. a voltage regulator in a system vs. a voltage regulator on an ATE). Similarly, the variations in temperature cannot be measured with the necessary precision to take into account the associated difference in sub-circuit performance caused by such temperature variation. Thus, comparing an aging and a non-aging circuit that are both effectively at identical temperatures and are coupled to the same power source gives a more accurate reference of absolute change between the circuits.

In some embodiments, aging circuit 210 is configured to be decoupled from power source 240 when an IC that includes degradation measurement circuit 200 operates in low-power mode. In such an embodiment, power consumption associated with running aging circuit 210 is eliminated at a time when available power is at a premium. Because degradation is generally greatly reduced for components of an IC when in low-power mode, the inaccuracy in degradation measurements associated with decoupling aging circuit 210 in such situations is slight.

In other embodiments, aging circuit 210 and reference circuit 220 are co-located on the IC containing degradation measurement circuit 200, or are disposed as close as practicable to each other. In this way, aging circuit 210 and reference circuit 220 can both be assumed to be at substantially identical temperatures. Because the output frequency of aging circuit 210 and reference circuit 220 is affected by temperature, collocation of aging circuit 210 and reference circuit 220 eliminates a significant source of error when measuring output frequencies thereof. Furthermore, in some embodiments, aging circuit 210 and reference circuit 220 have substantially the same orientation, to further insure that sources of error when measuring output frequencies are minimized.

As is well-known in the art, there are various mechanisms that can cause degradation of the components of an IC. Specifically, in one example, transistors subject to operating bias, whether or not the transistors are actually switched, exhibit changes in their operating characteristics over time. Such an effect is know as bias temperature instability (BTI). Typically, BTI causes transistor thresholds to increase, and other electrical parameters, such as drive current and transconductance, are also affected. According to embodiments of the invention, aging circuit 210 is configured to quantify the degradation experienced by target circuit 203 cause by operating bias. In such embodiments, aging circuit 210 is configured to be “usually stopped,” i.e., coupled to power source 240 during normal operation of the IC that includes target circuit 203 but in a static state and not oscillating. Thus, oscillating circuit 205A is subject to operating bias throughout the lifetime of degradation measurement circuit 200, but does not undergoes switching during normal operation. Instead, oscillating circuit 205A generally only oscillates during periodic testing, for example once per week or month, so that frequency counter 230 can measure the output frequency thereof. Such testing typically has very limited duration and results in insignificant degradation of the components of oscillating circuit 205A.

Another mechanism that can cause degradation of transistors in an IC to suffer degradation is due to the switching of said transistors. The high fields associated with increased switching speed are known to induce hot carrier injection (HCI), a phenomenon in which a charge carrier, i.e., an electron or a hole, gains sufficient kinetic energy to overcome a potential barrier necessary to break an interface state. The charge carrier can become trapped in the gate dielectric of a MOS transistor, permanently changing the switching characteristics of the transistor. According to embodiments of the invention, aging circuit 210 can be configured to quantify the degradation experienced by target circuit 203 caused by switching of transistors over the lifetime of target circuit 203. In such embodiments, aging circuit 210 is configured to be “usually on,” i.e., coupled to power source 240 during normal operation of target circuit 203 and continuously oscillating. Thus, oscillating circuit 205A is subject to continuous switching operations throughout the lifetime of degradation measurement circuit 200, as well as operating bias. During periodic testing, oscillating circuit 205A continues to oscillate so that an output frequency can be measured by frequency counter 230.

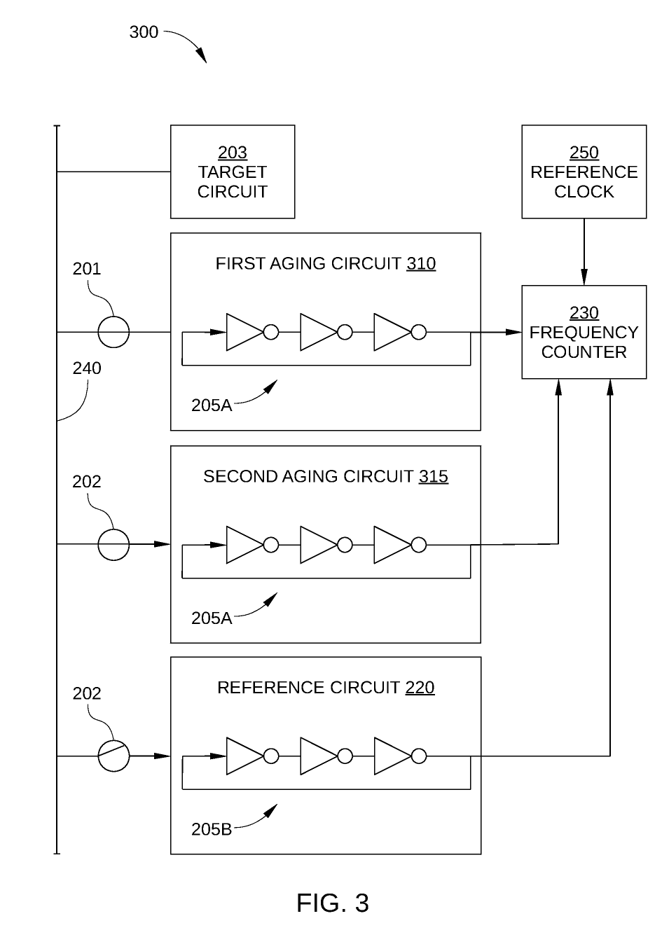

FIG. 3 is a schematic illustration of a degradation measurement circuit 300, according to one embodiment of the invention. Degradation measurement circuit 300 includes a first aging circuit 310, a second aging circuit 315, reference circuit 220, and frequency counter 230, and is configured to enable accurate measurement of the degradation of one or more portions of an IC, such as CPU 102 or processors in parallel processing subsystem 112 in FIG. 1, or any other IC. Degradation measurement circuit 300 is substantially similar in organization and operation to degradation measurement circuit 200 in FIG. 2, except that degradation measurement circuit 300 includes multiple aging circuits.

As shown, first aging circuit 310 is configured to enable measurement of components of an IC subject to degradation associated with operating bias and with switching. Second aging circuit 315 is configured to enable measurement of components of an IC subject to degradation associated with operating bias. Thus, first aging circuit 310 is configured to be usually on during normal operation of target circuit 203 and degradation measurement circuit 300, and is generally oscillating continuously. Second aging circuit 315 is configured to be usually stopped during normal operation of target circuit 203 and degradation measurement circuit 300, but does have supply voltage applied from power source 240. During testing, first aging circuit 310, second aging circuit 315, and reference circuit 220 provide outputs to frequency counter 230.

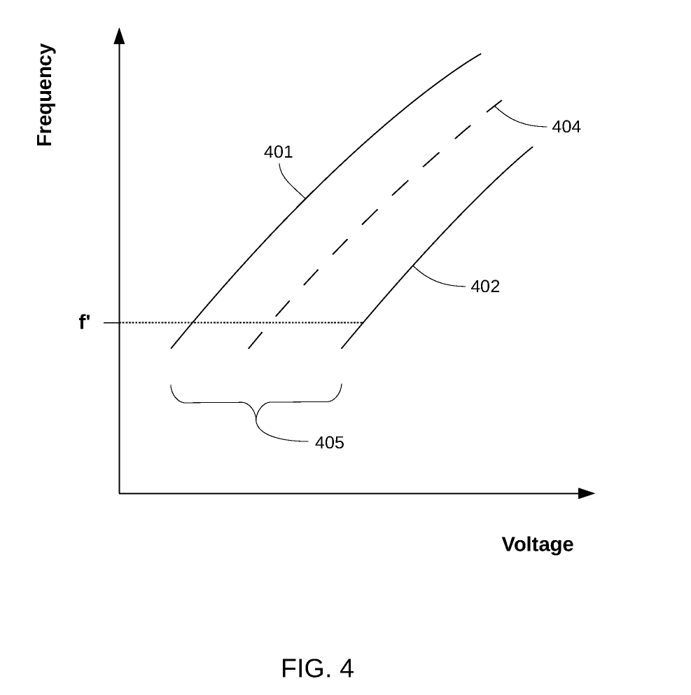

FIG. 4 is a graph illustrating voltage-frequency curves of an IC configured with degradation measurement circuit 200 and/or 300, according to one embodiment of the invention. FIG. 4 includes a beginning-of-life (BOL) voltage-frequency curve 401 and an end-of-life (EOL) voltage-frequency curve 402. BOL voltage-frequency curve 401 indicates, for a desired frequency, minimum recommended voltage at beginning-of-life for an IC or a particular component thereof, such as CPU 102 or parallel processing subsystem 112 in FIG. 1, etc. Similarly, EOL voltage-frequency curve 402 indicates, for a desired frequency, minimum recommended voltage at end-of-life for the IC or component of interest. It is noted that, for a desired frequency, running the IC or component at a voltage lower than a recommended voltage can result in functional failures, which are highly undesirable. It is further noted that BOL voltage-frequency curve 401 and EOL voltage-frequency curve 402 may already include voltage margin for phenomena generally unrelated to semiconductor device degradation that can also vary IC performance, such as voltage noise and manufacturing process variation.

As shown, for a particular desired frequency of operation, such as f, a higher voltage is recommended at end-of-life than at beginning-of-life, due to degradation of the IC or component over time. Without the measurements of degradation provided by a degradation measurement circuit, e.g., degradation measurement circuit 200 and/or 300, a worst-case scenario is generally assumed to guarantee that sufficient voltage margin is used. Specifically, a voltage margin 405 is incorporated into the operation of the IC or component. In other words, to avoid the occurrence of functional failures during the specified lifetime of the IC or component, EOL voltage-frequency curve 402 is typically used when implementing dynamic voltage and frequency scaling (DVFS). Consequently, over most of the useful lifetime of the IC or component, unnecessarily high power consumption and/or reduced performance is experienced. Similarly, a frequency margin may be used in lieu of or in addition to voltage margin 405, such as when voltage cannot be raised further. According to embodiments of the invention, an IC or component may be operated using a modified voltage-frequency curve 404, which is based on the periodic measurement taken using one or more degradation measurement circuits as described herein. Modified voltage-frequency curve 404 can be updated whenever the one or more degradation measurement circuits 200 and/or 300 associated with the IC or component are used to measure degradation of the IC or component. In this way, a minimum recommended voltage is used throughout the lifetime of the IC or component based on the actual condition thereof. This approach reduces energy requirements and/or increases computing performance of the IC or component.

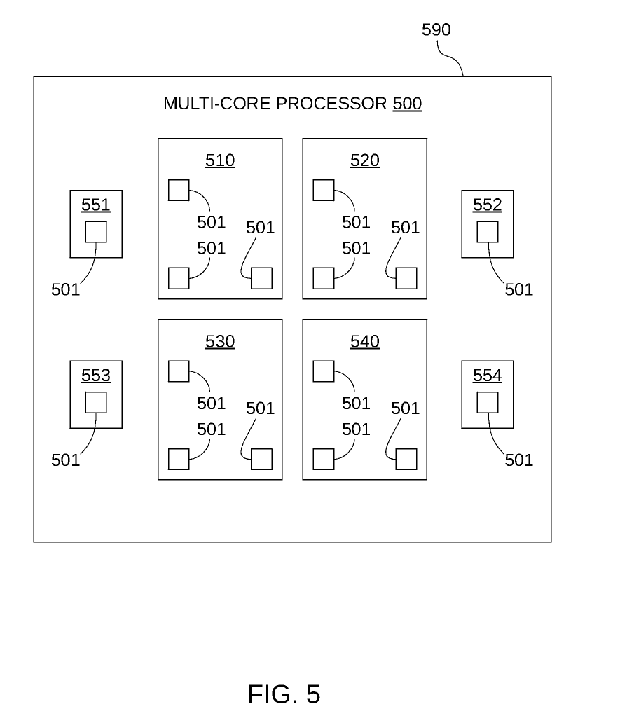

According to other embodiments of the invention, an IC or system, such as CPU 102 or parallel processing subsystem 112 in FIG. 1, may include multiple degradation measurement circuits. In such embodiments, one or more degradation measurement circuits may be included in each chip or component that is expected to have different usage than other parts of the IC or system. For instance, although a multi-core processor may include identical processor cores, over the lifetime of the multi-core processor, each core may experience different workloads and therefore experience different levels of degradation. One such embodiment is illustrated in FIG. 5.

FIG. 5 is a schematic illustration of a multi-core processor 500, according to one embodiment of the invention. Multi-core processor 500 may be a CPU, such as CPU 102 in FIG. 1, a parallel processing unit or graphics processing unit, such as a processor in parallel processing subsystem 112 in FIG. 1, or any other technically feasible microprocessor. In the embodiment illustrated in FIG. 5, multi-core processor 500 includes four processor cores 510, 520, 530, and 540 and peripheral logic blocks 551-554 formed on a single semiconductor die 590.

Each of processor cores 510, 520, 530, and 540, and each of peripheral logic blocks 551-554 may include one or more measurement circuits 501 formed as a sub-circuit. Measurement circuits 501 are substantially similar in configuration and operation to degradation measurement circuit 200 in FIG. 2 or degradation measurement circuit 300 in FIG. 3. In the embodiment illustrated in FIG. 5, the simpler peripheral logic blocks 551-554 may include a single measurement circuit 501; whereas, the more complex processor cores 510, 520, 530, and 540 each include multiple measurement circuits 501. In some embodiments, the multiple measurement circuits 501 in processor cores 510, 520, 530, and 540 can each be configured to test different sub-circuits or components of each processor core.

In other embodiments, the multiple measurement circuits 501 in processor cores 510, 520, 530, and 540 may also include redundant measurement circuits. Specifically, two or more of measurement circuits 501 on a particular processor core may be configured to measure the same characteristic. In such embodiments, the redundant measurement circuits can provide more accurate output, either by averaging, elimination of outlying measurements, etc.

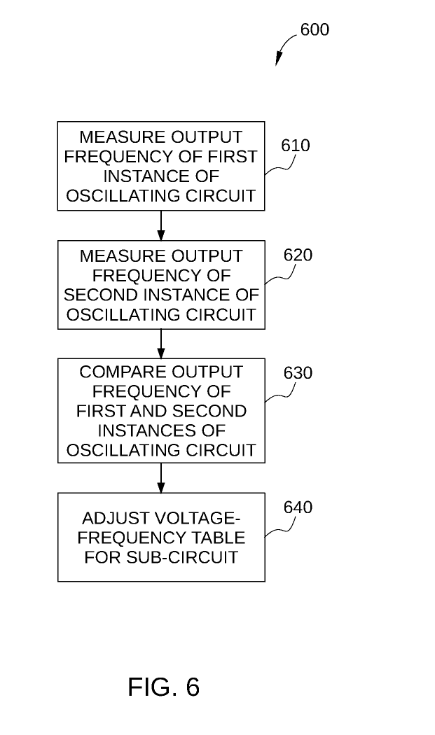

FIG. 6 is a flowchart of method steps for determining the degradation of a circuit in a semiconductor system, according to one embodiment of the present invention. Although the method steps are described in conjunction with the systems of FIGS. 1-6, persons skilled in the art will understand that any system configured to perform the method steps, in any order, is within the scope of the present invention. The control algorithms for the method steps may reside, among other locations, in system memory 104 or system disk 114 of computing system 100 in FIG. 1, or in a host associated therewith.

As shown, a method 600 begins at step 610, where a processor or other suitably configured device measures an output frequency of a first instance of an oscillating circuit, such as aging circuit 210 in FIG. 2. The first instance of the oscillating circuit is formed as part of the semiconductor system and is configured to be coupled to a power source during operation of the semiconductor system, thereby undergoing use-related degradation.

In step 620, the processor or other suitably configured device measures an output frequency of a second instance of the oscillating circuit, such as reference circuit 220 in FIG. 2. The second instance of the oscillating circuit is also formed as part of the semiconductor system and is configured to be decoupled from any power source during normal operation of the semiconductor system. Furthermore, the second instance of the oscillating circuit is configured to be, during a testing operation, coupled to the same power source as the first instance of the oscillating circuit. Because the second instance of the oscillating circuit is generally decoupled from any power source during normal operation of the semiconductor system being monitored, the second instance of the oscillating circuit can be used as a reference circuit to quantify in absolute terms degradation of a sub-circuit or other component in the semiconductor system.

In step 630, the processor or other suitably configured device compares the output frequency of the first instance to the output frequency of the second instance to determine behavior of a sub-circuit of the semiconductor system. Because the oscillating circuit is configured to be proportional to a particular characteristic of one or more sub-circuits or other components in the semiconductor system, such a comparison of output frequencies can provide a quantitative measurement of degradation of the sub-circuits or other components. Particular characteristics that may be monitored include a leakage rate of one or more types of transistors in the semiconductor system, a speed of one or more types of transistors in the semiconductor system, a critical path delay of the semiconductor system, a static random access memory speed of the semiconductor, and a wire delay of the semiconductor system.

In step 640, the processor or other suitably configured device adjusts a voltage-frequency table associated with operating the sub-circuit of interest in the semiconductor system, where the adjustment is based on the behavior of the sub-circuit of the semiconductor system determined in step 630. Such an adjustment allows the sub-circuit of interest to be operated using a modified voltage-frequency curve, such as modified voltage-frequency curve 404 in FIG. 4. Consequently, the sub-circuit can be operated with significantly less voltage margin over the majority of the operational lifetime thereof. In some embodiments, the voltage frequency table can be adjusted to require higher voltage to meet similar frequency or to clip max achievable frequency for a product over time. Voltage-frequency tables as referred to herein may reside, among other locations, in system memory 104 or system disk 114 of computing system 100 in FIG. 1, or in a host associated therewith.

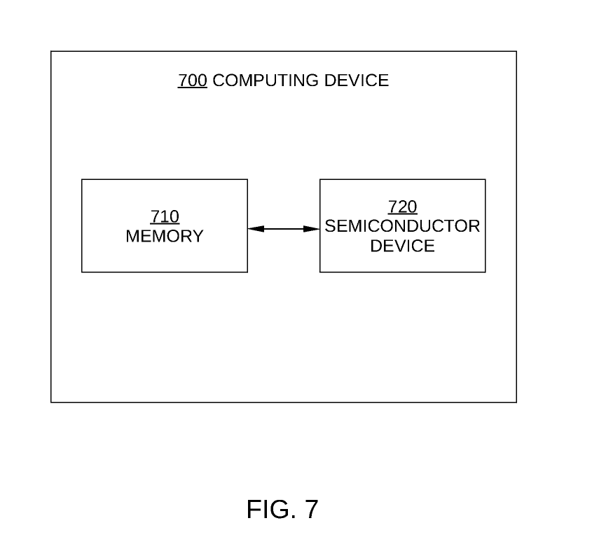

FIG. 7 illustrates a computing device in which one or more embodiments of the present invention can be implemented. Specifically, FIG. 7 is a block diagram of a computer system 700 with a semiconductor device 720 configured according to an embodiment of the present invention. As shown, computer system 700 includes a memory 710 and a semiconductor device 720 that is coupled to memory 710. Computer system 700 may be a desktop computer, a laptop computer, a smartphone, a digital tablet, a personal digital assistant, or other technically feasible computing device. Memory 710 may include volatile, non-volatile, and/or removable memory elements, such as random access memory (RAM), read-only memory (ROM), a magnetic or optical hard disk drive, a flash memory drive, and the like. Semiconductor device 720 is substantially similar in organization and operation to computing system 100 described above in conjunction with FIG. 1, and may comprise a CPU, a GPU, an application processor or other logic device, or any other IC-containing device.

In sum, embodiments of the invention set forth systems and methods for monitoring the degradation over time of one or more portions of an integrated circuit. A first instance and a second instance of an oscillating circuit are each formed as part of the integrated circuit being monitored, where the first instance of the oscillating circuit is configured to be coupled to a power source during normal operation of the integrated circuit and the second instance is configured to be decoupled from the power source. Over the lifetime of the integrated circuit being monitored, the first instance undergoes degradation from use corresponding to degradation of the integrated circuit while the second instance of the oscillating circuit remains unpowered, therefore experiencing essentially no use-related degradation. During a testing operation, the second instance can be used as a reference circuit that accurately quantifies use-related degradation of the first instance of the oscillating circuit and, by extension, one or more portions of the integrated circuit.

One advantage of the present invention is that accurate measurement of semiconductor degradation over time in an integrated circuit can be made periodically throughout the lifetime of the integrated circuit. This allows for significantly reduced voltage margins, thereby improving computing performance and reducing power consumption of the integrated circuit.

While the foregoing is directed to embodiments of the present invention, other and further embodiments of the invention may be devised without departing from the basic scope thereof, and the scope thereof is determined by the claims that follow.

We claim:

1. A method for determining the degradation of an integrated circuit, the method comprising:
measuring a first output frequency of a first instance of an oscillating circuit that is formed on a semiconductor substrate and is configured to be coupled to a power source during operation of the integrated circuit;
measuring a second output frequency of a second instance of the oscillating circuit that is formed on the semiconductor substrate, is decoupled from the power source during operation of the integrated circuit, and is configured to be coupled to the power source during a testing operation.

2. The method of claim 1, further comprising comparing the first output frequency to the second output frequency to determine a behavior of a sub-circuit within the integrated circuit.

3. The method of claim 2, further comprising, based on the behavior of the sub-circuit, adjusting a voltage-frequency table associated with operating the integrated circuit.

4. The method of claim 2, wherein the behavior of the sub-circuit varies as a result of usage-based degradation of the sub-circuit.

5. The method of claim 1, further comprising decoupling the second instance from the power source when the integrated circuit is in a low-power mode.

6. The method of claim 1, further comprising measuring a third output frequency of a third instance of the oscillating circuit that is formed on the semiconductor substrate and is configured to be coupled to the power source during operation of the integrated circuit.

7. The method of claim 6, wherein the first instance of the oscillating circuit is configured to oscillate during operation of the integrated circuit, and the second instance of the oscillating circuit is configured to remain in a static state during operation of the integrated circuit.

8. The method of claim 1, wherein measuring the second output frequency comprises coupling the second instance of the oscillating circuit to the power source.

9. The method of claim 1, wherein the first output frequency is proportional to either a transistor leakage rate associated with the integrated circuit, a transistor speed associated with the integrated circuit, a critical path delay associated with the integrated circuit, a static random access memory speed, or a wire delay associated with the integrated circuit.

10. An integrated circuit, comprising:
a first instance of an oscillating circuit that is formed on a semiconductor substrate and is configured to be coupled to a power source during operation of the integrated circuit; and
a second instance of the oscillating circuit that is formed on the semiconductor substrate, configured to be decoupled from the power source during operation of the integrated circuit, and configured to be coupled to the power source during a testing operation.

11. The integrated circuit of claim 10, wherein the second instance is further configured to be decoupled from the power source when the integrated circuit is in a low-power mode.

12. The integrated circuit of claim 1, further comprising a processor configured to compare the output frequency of the first instance to the output frequency of the second instance to determine a behavior of a sub-circuit within the integrated circuit.

13. The integrated circuit of claim 12, wherein the processor is further configured to, based on the behavior of the sub-circuit, adjust a voltage-frequency table associated with operating the integrated circuit.

14. The integrated circuit of claim 12, wherein the behavior of the sub-circuit varies as a result of usage-based degradation of the sub-circuit.

15. The integrated circuit of claim 12, wherein the sub-circuit is configured to be coupled to the power source during operation of the integrated circuit.

16. The integrated circuit of claim 10, wherein the processor is further configured to measure an output frequency of a third instance of the oscillating circuit that is formed on the semiconductor substrate and is configured to be coupled to the power source during operation of the integrated circuit.

17. The integrated circuit of claim 16, wherein the first instance of the oscillating circuit is configured to oscillate during operation of the integrated circuit and the second instance of the oscillating circuit is configured to remain in a static state during operation of the integrated circuit.

18. The integrated circuit of claim 10, wherein the first instance of the oscillating circuit and the second instance of the oscillating circuit each have the same orientation on the semiconductor substrate.

19. The integrated circuit of claim 10, wherein an output frequency of the first instance of the oscillating circuit is proportional to either a transistor leakage rate associated with the integrated circuit, a transistor speed associated with the integrated circuit, a critical path delay associated with the integrated circuit, a static random access memory speed associated with the integrated circuit, or a wire delay associated with the integrated circuit.

20. A computing device, comprising:
a memory; and
an integrated circuit coupled to the memory, wherein the integrated circuit comprises:
a first instance of an oscillating circuit that is formed on a semiconductor substrate and is configured to be coupled to a power source during operation of the integrated circuit; and
a second instance of the oscillating circuit that is formed on the semiconductor substrate, configured to be decoupled from the power source during operation of the integrated circuit, and coupled to the power source during a testing operation.
